(19) United States
(12) Patent Application Publication
(10) Pub. No.: US 2025/0210606 A1
(43) Pub. Date: Jun. 26, 2025

(54) SYSTEMS AND METHODS FOR THREE PART SYSTEM ON CHIP MEMORY STACKING

(71) Applicant: Meta Platforms Technologies, LLC, Menlo Park, CA (US)

(72) Inventors: Jaspreet Singh Gandhi, San Jose, CA (US); Rajendra D Pendse, Fremont, CA (US)

(21) Appl. No.: 18/390,993

(22) Filed: Dec. 20, 2023

(51) Int. Cl. H01L 25/18; H01L 23/00; H01L 23/538; H01L 25/00; H10B 80/00

(52) U.S. Cl. CPC H01L 25/18; H01L 23/5383; H01L 24/32; H01L 24/48; H01L 24/73; H01L 25/50; H10B 80/00; H01L 24/16; H01L 2224/16227; H01L 2224/32145; H01L 2224/32225; H01L 2224/48091; H01L 2224/48225; H01L 2224/73204; H01L 2224/73265; H01L 2924/1436; H01L 2924/1437

(57) ABSTRACT

A method for three part system on chip memory stacking may include positioning a packaging laminate substrate between a system on chip and a functional chip, wherein the functional chip is connected to the system on chip by a via stack included in the packaging laminate substrate. The method may also include mounting an additional functional chip on the system on chip and bonding the additional functional chip to the system on chip. Various other methods, systems, and computer-readable media are also disclosed.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a flow diagram of an exemplary method for three part system on chip memory stacking.

FIG. 2 is an illustration of an exemplary semiconductor device package that implements three part system on chip memory stacking.

FIG. 3 is an illustration of exemplary augmented-reality glasses that may be used in connection with embodiments of this disclosure.

FIG. 4 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Current technologies for system on chip (SoC) dynamic random access memory (SoC-DRAM) packaging in a mobile segment include traditional package on package (POP), integrated fanout (InFO) package on package (InFO_PoP), molded chip embedded package (MCep), and integrated package on package (iPoP). However, these technologies are limited to two part 3D stacking.

The present disclosure is generally directed to systems and methods for three part system on chip memory stacking. As will be explained in greater detail below, embodiments of the present disclosure may position a packaging laminate substrate between a system on chip and a functional chip, wherein the functional chip is connected to the system on chip by a via stack included in the packaging laminate substrate, mount an additional functional chip on the system on chip, and bond the additional functional chip to the system on chip. In some implementations, embodiments of the present disclosure may mount the additional functional chip back to back on the system on chip by an adhesive and bond the additional functional chip to the system on chip by wire bonding. In some implementations, the functional chip and the additional functional chip may correspond to memory, such as random access memory. In some of these implementations, the functional chip may correspond to an in-package memory that performs analogously to an on-chip static random access memory and the additional functional chip may correspond to a dynamic random access memory. In some implementations, the system on chip may correspond to a neural network accelerator configured to process images rendered to a display device of a space-constrained mobile device, such as a virtual reality headset and/or augmented reality glasses.

Benefits arising from the disclosed systems and methods may include achievement of three-part 3D stacking at reduced cost, reduced cycle time, and/or reduced package height. In some implementations, these benefits may enable a three-part system exhibiting a low-latency and high bandwidth in-package memory (e.g., that performs analogously to an on-chip SRAM), a highly functional SoC, and a high-capacity storage (e.g., DRAM) with reduced cost and cycle time and a reduced package height. This reduced package height may be beneficial in meeting form factor requirements for use of the disclosed systems and methods in space-constrained mobile devices, such as virtual reality (VR) headsets and augmented reality (AR) glasses. The reduced cost and cycle time may be beneficial in achieving space-constrained mobile devices, such as VR headsets and AR glasses, at reduced time and cost.

Features from any of the embodiments described herein may be used in combination with one another in accordance with the general principles described herein. These and other embodiments, features, and advantages will be more fully understood upon reading the following detailed description in conjunction with the accompanying drawings and claims.

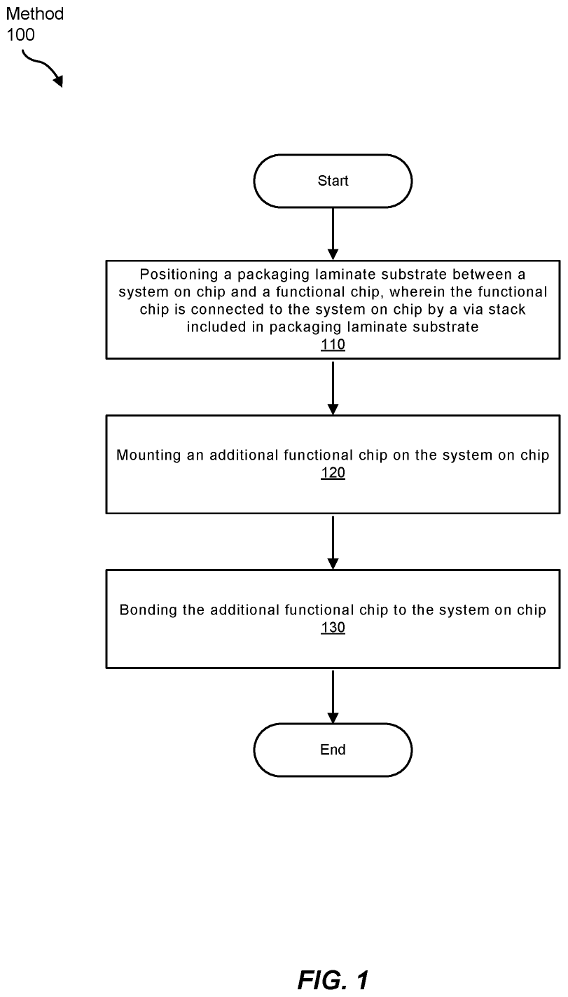

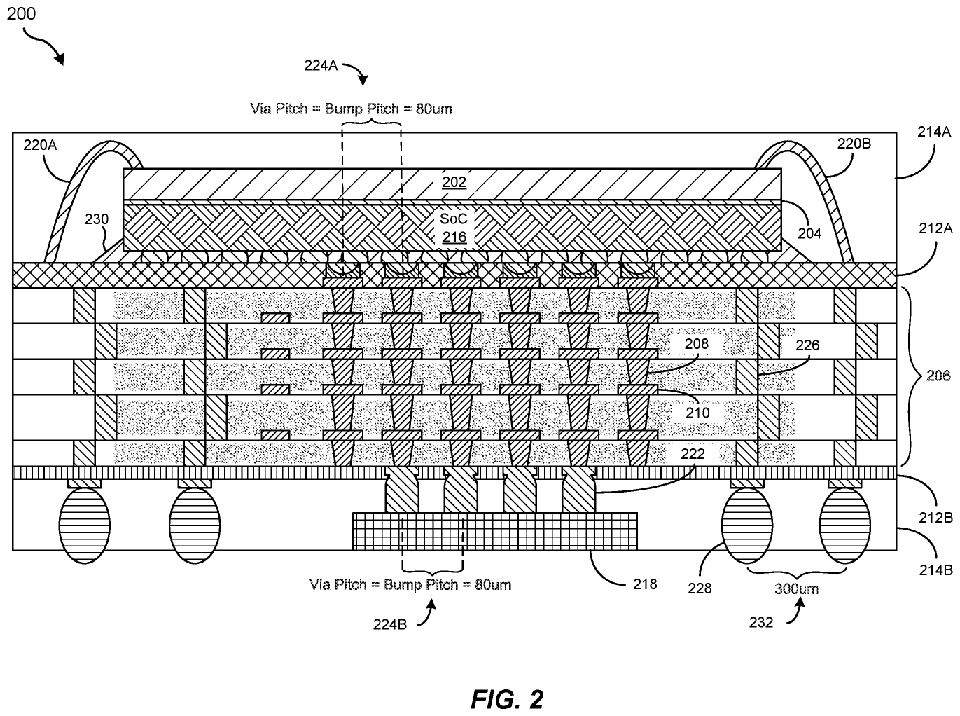

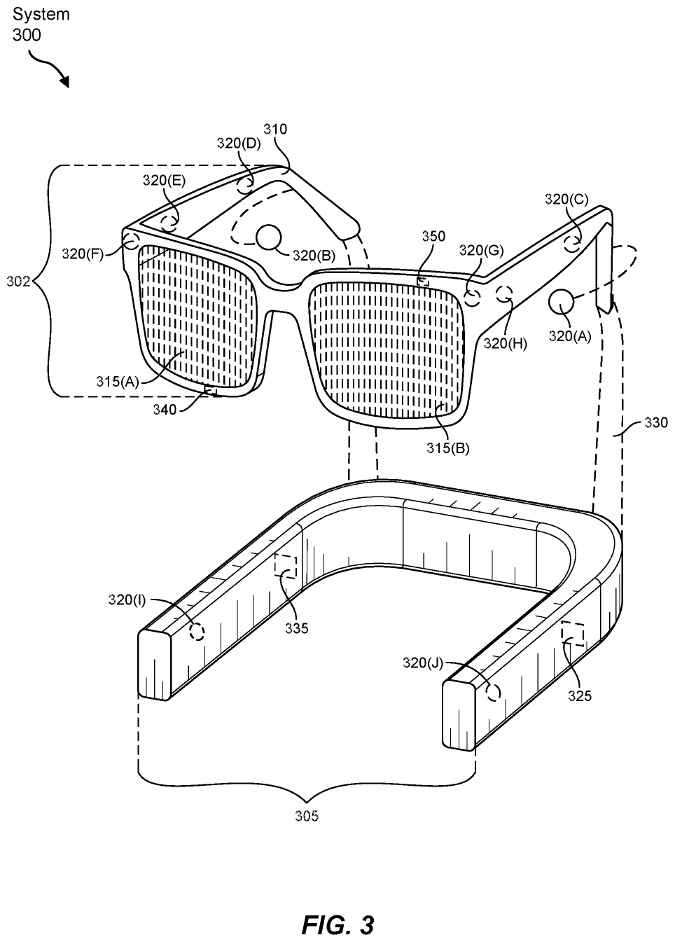

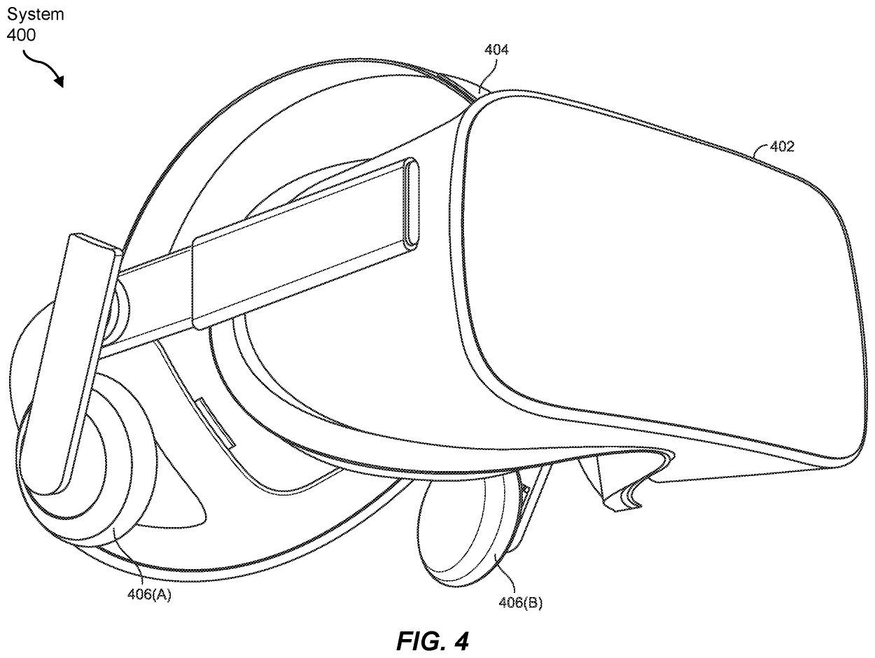

The following will provide, with reference to FIG. 1, detailed descriptions of exemplary methods for three part system on chip memory stacking. Exemplary semiconductor device packages for three part system on chip memory stacking will be provided in connection with FIG. 2. Further, detailed descriptions of exemplary augmented-reality glasses and virtual-reality headsets will be provided with reference to FIGS. 3 and 4.

FIG. 1 is a flow diagram of an exemplary method 100 for three part system on chip memory stacking. Beginning at step 110, method 100 may include positioning a packaging laminate substrate. For example, method 100, at step 110, may position a packaging laminate substrate between a system on chip and a functional chip, wherein the functional chip is connected to the system on chip by a via stack included in the packaging laminate substrate.

The term “packaging laminate substrate,” as used herein, may generally refer to multiple, thin layers of material stacked to form a rigid substrate. For example, and without limitation, packaging laminate substrate material may be made of stacked layers that correspond to epoxy (e.g., FR4) and/or resin (e.g., bismaleimide-triazine (BT)). In this context, “substrate” may generally refer to a part of a semiconductor device package that gives the board its mechanical strength and allows it to connect with external devices.

The term “system on chip,” as used herein, may generally refer to an integrated circuit that integrates most or all components of a computer or other electronic system. For example, and without limitation, these components may include an on-chip central processing unit (CPU), memory interfaces, input/output devices and interfaces, and secondary storage interfaces, often alongside other components such as radio modems and a graphics processing unit (GPU)—all on a single substrate or microchip. With an SoC, a chip might incorporate a CPU, plus an additional one-hundred IP blocks on the same chip. That design may then be scaled by moving to the next node, which is an expensive process. With a chiplet model, those one-hundred IP blocks may be hardened into smaller dies or chiplets.

The term “functional chip,” as used herein, may generally refer to a set of electronic circuits on a small flat piece of silicon. For example, and without limitation, a functional chip may correspond to a static random access memory (SRAM) or a dynamic random access memory (DRAM). In this context, the term “memory” may refer to an electronic holding place for instructions and data a computer needs to reach quickly. Also in this context, the term “static random access memory” may refer to a type of random access memory (RAM) that retains data bits in its memory as long as power is being supplied. In contrast, the term “dynamic random access memory” may refer to a type of RAM which must be continuously refreshed.

The term “via,” as used herein, may generally refer to an electrical connection. For example, and without limitation, a via may correspond to an electrical connection between different layers of a printed circuit board. Such a via may correspond to a small hole made through the PCB laminates that crosses two or more adjacent layers. Such a via may also be plated or filled with an electrically conductive material, such as metal (e.g., copper). In this context, vias may be formed in a packaging laminate substrate material by laser drilling and or photolithography. For example, CO2 laser drilling may form individual vias having a size in a range of forty to sixty micrometers. Alternatively, UV laser followed by excimer laser may drill even smaller individual vias. Moreover, lithography based photo vias may have a size of ten micrometers or less.

Method 100 may perform step 110 in various ways. For example, the functional chip may correspond to an in-package high speed local memory that performs analogously to an on-chip static random access memory. In some implementations, the via stack may be configured to provide direct via to via connection of the system on chip to the functional chip. Additionally or alternatively, the via stack may have a pitch in a range of forty to eighty micrometers. For example, the via stack may have a pitch no greater than eighty micrometers or, in some implementations, no greater than fifty micrometers. Additionally or alternatively, individual vias of the via stack may have a size in a range of ten to forty micrometers. For example, the Individual vias may have a size no greater than forty micrometers or, in some implementations, no greater than twelve micrometers. Additionally or alternatively, via pads corresponding to the individual vias may have a size in a range of twenty-five to sixty micrometers. For example, the via pads may have a size no greater than sixty micrometers or, in some implementations, no greater than twenty-five micrometers. Still other implementations may have narrower ranges of via pitch (e.g., forty to seventy micrometers, forty to sixty micrometers, forty to fifty micrometers, etc.), individual via size (e.g., ten to thirty micrometers, ten to twenty micrometers, ten to twelve micrometers, etc.), and via pad size (e.g., twenty-five to fifty micrometers, twenty-five to forty micrometers, twenty-five to thirty micrometers, etc.). In some implementations, the packaging laminate substrate may include a plurality of peripheral stack vias configured to supply power and input-output routing to the system on chip and the functional chip.

At step 120, method 100 may include mounting an additional functional chip. For example, method 100, at step 120, may mount an additional functional chip on the system on chip.

Method 100 may perform step 120 in various ways. For example, method 100 may at step 120, mount the additional functional chip back to back on the system on chip by an adhesive. In some implementations, the additional functional chip may correspond to a dynamic random access memory.

At step 130, method 100 may include bonding the additional functional chip. For example, method 100, at step 130, may bond the additional functional chip to the system on chip.

Method 100 may perform step 130 in various ways. For example, method 100 may at step 130, bond the additional functional chip to the system on chip by wire bonding. Alternatively or additionally, method 100 may at step 130, surround the system on chip and the additional functional chip with a mold material.

The term “wire bonding,” as used herein, may generally refer to a method of making interconnections between an integrated circuit (IC) or other semiconductor device and its packaging during semiconductor device fabrication. For example, and without limitation, wire bonding may be used to connect an IC to other electronics or to connect from one printed circuit board (PCB) to another. Wire bonding may generally be considered the most cost-effective and flexible interconnect technology and may be used to assemble the vast majority of semiconductor packages.

The term “mold material,” as used herein, may generally refer to a mold compound. For example, and without limitation, mold compounds may be composite materials that include organic resins, such as epoxy resin, which may be melted. Given the natural adhesive properties of epoxy resins, these compounds may also include a mold release agent to enable the extraction of the component from a mold. Phenolic hardeners, silicas, pigments, and catalysts may also be featured in mold compounds to accelerate cure reactions. In this context, mold compounds may be used to encapsulate a range of electronic packages, including capacitors, transistors, central processing units, and memory devices. In basic terms, the process may be considered in two stages. First, the components to be encapsulated may be transferred into mold cavities. Following this stage, a mold compound, having been liquefied by either heat or pressure, may be forced into the cavity where it may solidify into a plastic encapsulated device. Molding processes may also include an underfill, which may correspond to an adhesive. For example, and without limitation, the underfill may be dispensed on a flip-chip placement site. The chip may then be placed on top of the underfill under force to press the die into the fluid and the bumps into contact with the pads.

FIG. 2 illustrates an exemplary semiconductor device package 200 that implements three part system on chip memory stacking and that may be formed according to the method of FIG. 1. For example, a fine via stack laminate 206 may include two or more layers (e.g., three layers (3L), five layers (5L), etc.). Each of the layers may include a plurality of vias 208 having corresponding via pads 210. The individual vias 208 may have a size (e.g., diameter) in a range of ten to forty micrometers and the pads 210 may have a size (e.g., diameter) in a range of twenty-five to sixty micrometers. The pluralities of vias may stack with one another to form the fine via stack of the laminate 206. Dielectric material layers 212A and 212B may be arranged above and below the fine via stack laminate 206 and mold material 214A and 214B may be arranged above and below the dielectric material layers 212A and 212B.

As shown in FIG. 2, a functional chip 218 may have bumps 222 that may be situated in the mold material 214B along with the functional chip 218 as shown. An SoC 216 may be held in place by mold material 214A on one side of the fine via stack laminate 206 with its own bumps in contact with the pads corresponding to vias of the fine via stack laminate 206. Similarly, the functional chip 218 may be held in place by mold material 214B on an opposite side of the fine via stack laminate 206 with its bumps 222 in contact with the fine via stack of laminate 206. Accordingly, vias 208, pads 210, bumps 222, and bumps of the SoC 216 may all have a same pitch 224A and 224B, such as a same pitch in a range of forty to eighty micrometers.

As shown in FIG. 2, the fine via stack laminate 206 may include a plurality of peripheral stack vias 226 configured to supply power and input-output routing to the SoC 216 and the functional chip 218. These peripheral stack vias 226 may have corresponding balls of ball grid array 228 at least partially enclosed by the mold material 214B. For example, ball grid array 228 may have a pitch 232 of three hundred micrometers.

As shown in FIG. 2, the semiconductor device package 200 may include an additional functional chip 202 mounted on and bonded to the SoC 216. In some implementations, the additional functional chip 202 may be mounted back to back on the SoC 216 by an adhesive 204 and bonded to the system on chip by wire bonds 220A and 220B. In some implementations, the functional chips 218 may correspond to an in-package high speed local memory that performs analogously to an on-chip static random access memory. Additionally or alternatively, the additional functional chip 202 may correspond to a dynamic random access memory.

As shown in FIG. 2, the mold material 214A may surround the SoC 216 and the additional functional chip 202. Wire bonds 220A and 220B may also be surrounded by the mold material 214A. In some implementations, an under fill 230 may be provided around connection elements (e.g., micro bumps) that connect the SoC 216 to the pads of the via stack as shown in FIG. 2.

As set forth above, the disclosed systems and methods may position a packaging laminate substrate between a system on chip and a functional chip, wherein the functional chip is connected to the system on chip by a via stack included in the packaging laminate substrate, mount an additional functional chip on the system on chip, and bond the additional functional chip to the system on chip. In some implementations, the disclosed systems and methods may mount the additional functional chip back to back on the system on chip by an adhesive and bond the additional functional chip to the system on chip by wire bonding. In some implementations, the functional chip and the additional functional chip may correspond to memory, such as random access memory. In some of these implementations, the functional chip may correspond to an in-package memory that performs analogously to an on-chip static random access memory and the additional functional chip may correspond to a dynamic random access memory. In some implementations, the system on chip may correspond to a neural network accelerator configured to process images rendered to a display device of a space-constrained mobile device, such as a virtual reality headset and/or augmented reality glasses.

Benefits arising from the disclosed systems and methods may include achievement of three-part 3D stacking at reduced cost, reduced cycle time, and/or reduced package height. In some implementations, these benefits may enable a three-part system exhibiting a low-latency and high bandwidth in-package memory (e.g., that performs analogously to an on-chip SRAM), a highly functional SoC, and a high-capacity storage (e.g., DRAM) with reduced cost and cycle time and a reduced package height. This reduced package height may be beneficial in meeting form factor requirements for use of the disclosed systems and methods in space-constrained mobile devices, such as virtual reality (VR) headsets and augmented reality (AR) glasses. The reduced cost and cycle time may be beneficial in achieving space-constrained mobile devices, such as VR headsets and AR glasses, at reduced time and cost.

### Example Embodiments

Example 1: A semiconductor device package may include a system on chip, a functional chip connected to the system on chip by a via stack included in a packaging laminate substrate positioned between the system on chip and the functional chip, and an additional functional chip mounted on and bonded to the system on chip.
Example 2: The semiconductor device package of Example 1, wherein the additional functional chip is mounted back to back on the system on chip by an adhesive and bonded to the system on chip by wire bonding.
Example 3: The semiconductor device package of any of Examples 1 and 2, wherein the additional functional chip corresponds to a dynamic random access memory.
Example 4: The semiconductor device package of any of Examples 1 to 3, wherein the functional chip corresponds to an in-package high speed local memory that performs analogously to an on-chip static random access memory.
Example 5: The semiconductor device package of any of Examples 1 to 4, wherein the via stack is configured to provide direct via to via connection of the system on chip to the functional chip.
Example 6: The semiconductor device package of any of Examples 1 to 5, further comprising a mold material surrounding the system on chip and the additional functional chip.
Example 7: The semiconductor device package of any of Examples 1 to 6, wherein the via stack has a pitch in a range of forty to eighty micrometers.
Example 8: The semiconductor device package of any of Examples 1 to 7, wherein individual vias of the via stack have a size in a range of ten to forty micrometers.
Example 9: The semiconductor device package of any of Examples 1 to 8, wherein the packaging laminate substrate further includes a plurality of peripheral stack vias configured to supply power and input-output routing to the system on chip and the functional chip.
Example 10: A method may include positioning a packaging laminate substrate between a system on chip and a functional chip, wherein the functional chip is connected to the system on chip by a via stack included in the packaging laminate substrate, mounting an additional functional chip on the system on chip, and bonding the additional functional chip to the system on chip.
Example 11: The method of Example 10, wherein the additional functional chip is mounted back to back on the system on chip by an adhesive and bonded to the system on chip by wire bonding.
Example 12: The method of any of Examples 10 and 11, wherein the additional functional chip corresponds to a dynamic random access memory.
Example 13: The method of any of Examples 10 to 12, wherein the functional chip corresponds to an in-package high speed local memory that performs analogously to an on-chip static random access memory.
Example 14: The method of any of Examples 10 to 13, wherein the via stack is configured to provide direct via to via connection of the system on chip to the functional chip.
Example 15: The method of any of Examples 10 to 14, further comprising surrounding the system on chip and the additional functional chip with a mold material.
Example 16: The method of any of Examples 10 to 15, wherein the via stack has a pitch in a range of forty to eighty micrometers.
Example 17: The method of any of Examples 10 to 16, wherein individual vias of the via stack have a size in a range of ten to forty micrometers.
Example 18: The method of any of Examples 10 to 17, wherein the packaging laminate substrate further includes a plurality of peripheral stack vias configured to supply power and input-output routing to the system on chip and the functional chip.
Example 19: A system may include a display device and a semiconductor device package configured to process images rendered to the display device, wherein the semiconductor device package includes a system on chip, a functional chip connected to the system on chip by a via stack included in a packaging laminate substrate positioned between the system on chip and the functional chip, and an additional functional chip mounted on and bonded to the system on chip.
Example 20: The system of Example 19, wherein the additional functional chip is mounted back to back on the system on chip by an adhesive and bonded to the system on chip by wire bonding.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 300 in FIG. 3) or that visually immerses a user in an artificial reality (such as, e.g., virtual-reality system 400 in FIG. 4). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 3, augmented-reality system 300 may include an eyewear device 302 with a frame 310 configured to hold a left display device 315(A) and a right display device 315(B) in front of a user's eyes. Display devices 315(A) and 315(B) may act together or independently to present an image or series of images to a user. While augmented-reality system 300 includes two displays, embodiments of this disclosure may be implemented in augmented-reality systems with a single NED or more than two NEDs.

In some embodiments, augmented-reality system 300 may include one or more sensors, such as sensor 340. Sensor 340 may generate measurement signals in response to motion of augmented-reality system 300 and may be located on substantially any portion of frame 310. Sensor 340 may represent one or more of a variety of different sensing mechanisms, such as a position sensor, an inertial measurement unit (IMU), a depth camera assembly, a structured light emitter and/or detector, or any combination thereof. In some embodiments, augmented-reality system 300 may or may not include sensor 340 or may include more than one sensor. In embodiments in which sensor 340 includes an IMU, the IMU may generate calibration data based on measurement signals from sensor 340. Examples of sensor 340 may include, without limitation, accelerometers, gyroscopes, magnetometers, other suitable types of sensors that detect motion, sensors used for error correction of the IMU, or some combination thereof.

In some examples, augmented-reality system 300 may also include a microphone array with a plurality of acoustic transducers 320(A)-320(J), referred to collectively as acoustic transducers 320. Acoustic transducers 320 may represent transducers that detect air pressure variations induced by sound waves. Each acoustic transducer 320 may be configured to detect sound and convert the detected sound into an electronic format (e.g., an analog or digital format). The microphone array in FIG. 3 may include, for example, ten acoustic transducers: 320(A) and 320(B), which may be designed to be placed inside a corresponding ear of the user, acoustic transducers 320(C), 320(D), 320(E), 320(F), 320(G), and 320(H), which may be positioned at various locations on frame 310, and/or acoustic transducers 320(I) and 320(J), which may be positioned on a corresponding neckband 305.

In some embodiments, one or more of acoustic transducers 320(A)-(J) may be used as output transducers (e.g., speakers). For example, acoustic transducers 320(A) and/or 320(B) may be earbuds or any other suitable type of headphone or speaker.

The configuration of acoustic transducers 320 of the microphone array may vary. While augmented-reality system 300 is shown in FIG. 3 as having ten acoustic transducers 320, the number of acoustic transducers 320 may be greater or less than ten. In some embodiments, using higher numbers of acoustic transducers 320 may increase the amount of audio information collected and/or the sensitivity and accuracy of the audio information. In contrast, using a lower number of acoustic transducers 320 may decrease the computing power required by an associated controller 350 to process the collected audio information. In addition, the position of each acoustic transducer 320 of the microphone array may vary. For example, the position of an acoustic transducer 320 may include a defined position on the user, a defined coordinate on frame 310, an orientation associated with each acoustic transducer 320, or some combination thereof.

Acoustic transducers 320(A) and 320(B) may be positioned on different parts of the user's ear, such as behind the pinna, behind the tragus, and/or within the auricle or fossa. Or, there may be additional acoustic transducers 320 on or surrounding the ear in addition to acoustic transducers 320 inside the ear canal. Having an acoustic transducer 320 positioned next to an ear canal of a user may enable the microphone array to collect information on how sounds arrive at the ear canal. By positioning at least two of acoustic transducers 320 on either side of a user's head (e.g., as binaural microphones), augmented-reality system 300 may simulate binaural hearing and capture a 3D stereo sound field around about a user's head. In some embodiments, acoustic transducers 320(A) and 320(B) may be connected to augmented-reality system 300 via a wired connection 330, and in other embodiments acoustic transducers 320(A) and 320(B) may be connected to augmented-reality system 300 via a wireless connection (e.g., a BLUETOOTH connection). In still other embodiments, acoustic transducers 320(A) and 320(B) may not be used at all in conjunction with augmented-reality system 300.

Acoustic transducers 320 on frame 310 may be positioned in a variety of different ways, including along the length of the temples, across the bridge, above or below display devices 315(A) and 315(B), or some combination thereof. Acoustic transducers 320 may also be oriented such that the microphone array is able to detect sounds in a wide range of directions surrounding the user wearing the augmented-reality system 300. In some embodiments, an optimization process may be performed during manufacturing of augmented-reality system 300 to determine relative positioning of each acoustic transducer 320 in the microphone array.

In some examples, augmented-reality system 300 may include or be connected to an external device (e.g., a paired device), such as neckband 305. Neckband 305 generally represents any type or form of paired device. Thus, the following discussion of neckband 305 may also apply to various other paired devices, such as charging cases, smart watches, smart phones, wrist bands, other wearable devices, hand-held controllers, tablet computers, laptop computers, other external compute devices, etc.

As shown, neckband 305 may be coupled to eyewear device 302 via one or more connectors. The connectors may be wired or wireless and may include electrical and/or non-electrical (e.g., structural) components. In some cases, eyewear device 302 and neckband 305 may operate independently without any wired or wireless connection between them. While FIG. 3 illustrates the components of eyewear device 302 and neckband 305 in example locations on eyewear device 302 and neckband 305, the components may be located elsewhere and/or distributed differently on eyewear device 302 and/or neckband 305. In some embodiments, the components of eyewear device 302 and neckband 305 may be located on one or more additional peripheral devices paired with eyewear device 302, neckband 305, or some combination thereof.

Pairing external devices, such as neckband 305, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 300 may be provided by a paired device or shared between a paired device and an eyewear device, thus reducing the weight, heat profile, and form factor of the eyewear device overall while still retaining desired functionality. For example, neckband 305 may allow components that would otherwise be included on an eyewear device to be included in neckband 305 since users may tolerate a heavier weight load on their shoulders than they would tolerate on their heads. Neckband 305 may also have a larger surface area over which to diffuse and disperse heat to the ambient environment. Thus, neckband 305 may allow for greater battery and computation capacity than might otherwise have been possible on a stand-alone eyewear device. Since weight carried in neckband 305 may be less invasive to a user than weight carried in eyewear device 302, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 305 may be communicatively coupled with eyewear device 302 and/or to other devices. These other devices may provide certain functions (e.g., tracking, localizing, depth mapping, processing, storage, etc.) to augmented-reality system 300. In the embodiment of FIG. 3, neckband 305 may include two acoustic transducers (e.g., 320(I) and 320(J)) that are part of the microphone array (or potentially form their own microphone subarray). Neckband 305 may also include a controller 325 and a power source 335.

Acoustic transducers 320(I) and 320(J) of neckband 305 may be configured to detect sound and convert the detected sound into an electronic format (analog or digital). In the embodiment of FIG. 3, acoustic transducers 320(1) and 320(J) may be positioned on neckband 305, thereby increasing the distance between the neckband acoustic transducers 320(I) and 320(J) and other acoustic transducers 320 positioned on eyewear device 302. In some cases, increasing the distance between acoustic transducers 320 of the microphone array may improve the accuracy of beamforming performed via the microphone array. For example, if a sound is detected by acoustic transducers 320(C) and 320(D) and the distance between acoustic transducers 320(C) and 320(D) is greater than, e.g., the distance between acoustic transducers 320(D) and 320(E), the determined source location of the detected sound may be more accurate than if the sound had been detected by acoustic transducers 320(D) and 320(E).

Controller 325 of neckband 305 may process information generated by the sensors on neckband 305 and/or augmented-reality system 300. For example, controller 325 may process information from the microphone array that describes sounds detected by the microphone array. For each detected sound, controller 325 may perform a direction-of-arrival (DOA) estimation to estimate a direction from which the detected sound arrived at the microphone array. As the microphone array detects sounds, controller 325 may populate an audio data set with the information. In embodiments in which augmented-reality system 300 includes an inertial measurement unit, controller 325 may compute all inertial and spatial calculations from the IMU located on eyewear device 302. A connector may convey information between augmented-reality system 300 and neckband 305 and between augmented-reality system 300 and controller 325. The information may be in the form of optical data, electrical data, wireless data, or any other transmittable data form. Moving the processing of information generated by augmented-reality system 300 to neckband 305 may reduce weight and heat in eyewear device 302, making it more comfortable to the user.

Power source 335 in neckband 305 may provide power to eyewear device 302 and/or to neckband 305. Power source 335 may include, without limitation, lithium-ion batteries, lithium-polymer batteries, primary lithium batteries, alkaline batteries, or any other form of power storage. In some cases, power source 335 may be a wired power source. Including power source 335 on neckband 305 instead of on eyewear device 302 may help better distribute the weight and heat generated by power source 335.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 400 in FIG. 4, that mostly or completely covers a user's field of view. Virtual-reality system 400 may include a front rigid body 402 and a band 404 shaped to fit around a user's head. Virtual-reality system 400 may also include output audio transducers 406(A) and 406(B). Furthermore, while not shown in FIG. 4, front rigid body 402 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 300 and/or virtual-reality system 400 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 300 and/or virtual-reality system 400 may include microLED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 300 and/or virtual-reality system 400 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance.

Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

The process parameters and sequence of the steps described and/or illustrated herein are given by way of example only and may be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

What is claimed is:

1. A semiconductor device package, comprising:
a system on chip;
a functional chip connected to the system on chip by a via stack included in a packaging laminate substrate positioned between the system on chip and the functional chip; and
an additional functional chip mounted on and bonded to the system on chip.

2. The semiconductor device package of claim 1, wherein the additional functional chip is mounted back to back on the system on chip by an adhesive and bonded to the system on chip by wire bonding.

3. The semiconductor device package of claim 1, wherein the additional functional chip corresponds to a dynamic random access memory.

4. The semiconductor device package of claim 1, wherein the functional chip corresponds to an in-package high speed local memory that performs analogously to an on-chip static random access memory.

5. The semiconductor device package of claim 1, wherein the via stack is configured to provide direct via to via connection of the system on chip to the functional chip.

6. The semiconductor device package of claim 1, further comprising a mold material surrounding the system on chip and the additional functional chip.

7. The semiconductor device package of claim 1, wherein the via stack has a pitch in a range of forty to eighty micrometers.

8. The semiconductor device package of claim 1, wherein individual vias of the via stack have a size in a range of ten to forty micrometers.

9. The semiconductor device package of claim 1, wherein the packaging laminate substrate further includes a plurality of peripheral stack vias configured to supply power and input-output routing to the system on chip and the functional chip.

10. A method, comprising:
positioning a packaging laminate substrate between a system on chip and a functional chip, wherein the functional chip is connected to the system on chip by a via stack included in the packaging laminate substrate;
mounting an additional functional chip on the system on chip; and
bonding the additional functional chip to the system on chip.

11. The method of claim 10, wherein the additional functional chip is mounted back to back on the system on chip by an adhesive and bonded to the system on chip by wire bonding.

12. The method of claim 10, wherein the additional functional chip corresponds to a dynamic random access memory.

13. The method of claim 10, wherein the functional chip corresponds to an in-package high speed local memory that performs analogously to an on-chip static random access memory.

14. The method of claim 10, wherein the via stack is configured to provide direct via to via connection of the system on chip to the functional chip.

15. The method of claim 10, further comprising surrounding the system on chip and the additional functional chip with a mold material.

16. The method of claim 10, wherein the via stack has a pitch in a range of forty to eighty micrometers.

17. The method of claim 10, wherein individual vias of the via stack have a size in a range of ten to forty micrometers.

18. The method of claim 10, wherein the packaging laminate substrate further includes a plurality of peripheral stack vias configured to supply power and input-output routing to the system on chip and the functional chip.

19. A system, comprising:
a display device; and
a semiconductor device package configured to process images rendered to the display device, wherein the semiconductor device package includes:
a system on chip;
a functional chip connected to the system on chip by a via stack included in a packaging laminate substrate positioned between the system on chip and the functional chip; and
an additional functional chip mounted on and bonded to the system on chip.

20. The system of claim 19, wherein the additional functional chip is mounted back to back on the system on chip by an adhesive and bonded to the system on chip by wire bonding.
